(19) United States
(12) Patent Application Publication
(10) Pub. No.: US 2010/0155021 A1
(43) Pub. Date: Jun. 24, 2010

(54) Heat exchange cooling structure

(76) Inventors: Chin Hsiang Chiang, Chiunglin Township (TW); Hsing-Tang Liu, Chupei City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/318,066

(22) Filed: Dec. 22, 2008

(51) Int. Cl. F28F 7/00; H05K 7/20

(52) U.S. Cl. 165/80.2; 165/185; 361/704

(57) ABSTRACT

A heat exchange cooling structure includes a LED module, a heat spreader plate bonded to the bottom surface of the substrate of the LED module, and an electronic ceramic cooling plate made of a nano-scale inorganic semiconductor material through a sintering process and bonded to the bottom side of the heat spreader plate for dissipating heat from the heat spreader plate by means of a thermoelectric effect produced in millions of parallel-connected and series-connected N-P interfaces in the nano-scale inorganic semiconductor material.

### BACKGROUND OF THE INVENTION

1. Field of the Invention

The present invention relates to cooling technology and more particularly, to a heat exchange cooling structure, which uses a heat spreader plate to absorb and spread heat from a heat source, for example, a LED module, and an electronic ceramic cooling plate to dissipate heat from the heat spreader plate.

2. Description of the Related Art

FIG. 3 illustrates a LED cooling design according to the prior art. According to this design, a heat spreader 6 is bonded to the bottom side of the LED 5 to absorb and spread heat from the LED 5, enabling heat to be dissipated from the LED 5 into the outside open air. FIG. 4 illustrates another LED cooling design according to the prior art. According to this design, a heat spreader 6 is bonded to the bottom side of the LED 5 to absorb and spread heat from the LED 5, and radiation fins 61 are perpendicularly extended from the bottom side of the heat spreader 6 for quick dissipation of heat from the heat spreader 6 into the outside open air. The aforesaid two LED cooling designs must have the heat spreader be exposed to the outside for heat exchange with the outside open air. If the heat spreader 6 is enclosed in a shell, the heat spreader 6 will be unable to make heat exchange with the outside open air.

### SUMMARY OF THE INVENTION

The present invention has been accomplished under the circumstances in view. It is one object of the present invention to provide a heat exchange cooling structure, which utilizes external heat energy to cause internal molecules thereof to collide with one another in producing infrared rays for quick dissipation of heat from the heat source.

It is another object of the present invention to provide a heat exchange cooling structure, which utilizes generated infrared rays to carry heat out of an enclosed shell, achieving quick dissipation of heat from the enclosed external object.

To achieve these and other objects of the present invention, a heat exchange cooling structure comprises a heat generating device that generates heat during its operation, a heat spreader plate bonded to the bottom surface of the heat generating device, and an electronic ceramic cooling plate made of a nano-scale inorganic semiconductor material through a sintering process and bonded to the bottom side of the heat spreader plate for dissipating heat from the heat spreader plate by means of a thermoelectric effect produced in millions of parallel-connected and series-connected N-P interfaces in the nano-scale inorganic semiconductor material.

Further, the heat generating device can be a LED module, a CPU, or any electronic device of integrated circuit.

### BRIEF DESCRIPTION OF THE DRAWINGS

FIG. 1 is an exploded view of the present invention.

FIG. 2 is an elevational assembly view of the present invention.

FIG. 3 is a sectional assembly view of a LED mounting structure according to the prior art.

FIG. 4 is a sectional assembly view of another design of LED mounting structure according to the prior art.

### DETAILED DESCRIPTION OF THE PREFERRED EMBODIMENT

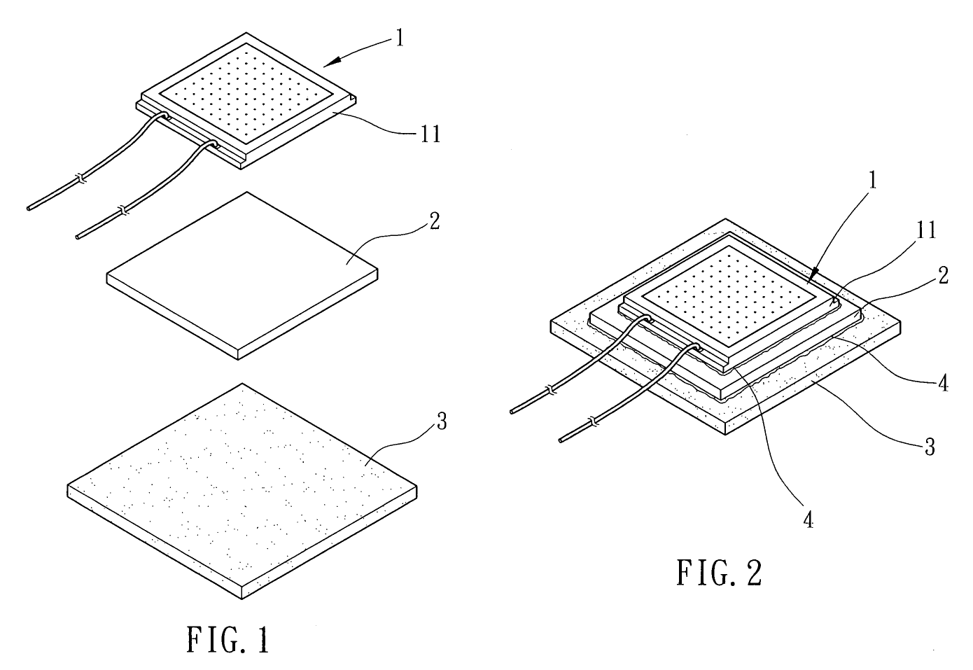

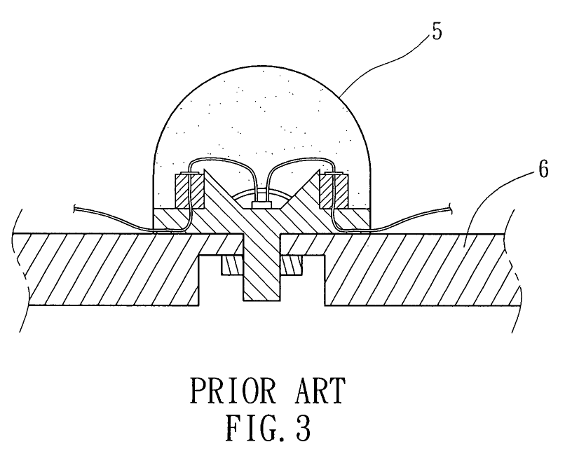

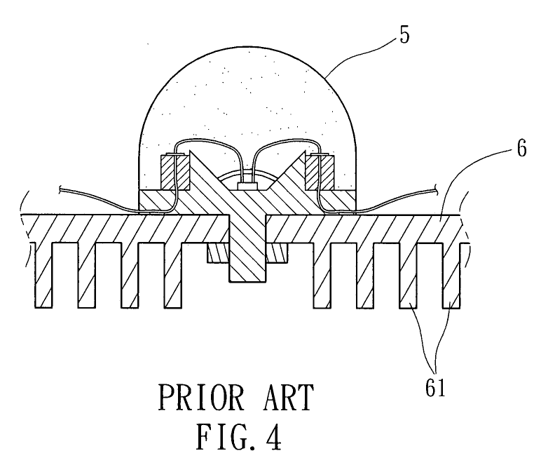

Referring to FIGS. 1˜3, a heat exchange cooling structure comprises a LED module 1 having a substrate 11, a heat spreader plate 2 provided at the bottom side of the LED module 1, and an electronic ceramic cooling plate 3 provided at the bottom side of the heat spreader plate 2. The heat spreader plate 2 is made of gold, silver, copper or aluminum that has a very high heat transfer rate.

During operation of the LED module 1, heat generated by the LED module 1 is transferred from the substrate 11 to the heat spreader plate 2 and then to the electronic ceramic cooling plate 3 for quick dissipation.

The electronic ceramic cooling plate 3 is made of a nano-scale inorganic semiconductor material through a sintering process, comprising millions of parallel-connected and series-connected N-P interfaces connected in parallel and in series. The cooling effect of the electronic ceramic cooling plate 3 utilizes the thermal electromotive force produced subject to a temperature difference between the heat source and the electronic ceramic cooling plate 3 and the internal N and P types semiconductors of the electronic ceramic cooling plate 3 to change current flowing direction so that the semiconductors absorb heat and simultaneously release heat. When the electronic ceramic cooling plate 3 is receiving heat from the heat spreader plate 2, the internal molecules of the electronic ceramic cooling plate 3 are caused to collide with one another, thereby producing infrared rays to carry heat energy away, and therefore heat is quickly dissipated from the LED module 1 and the heat spreader plate 2 by the electronic ceramic cooling plate 3 to the outside open air.

The electronic ceramic cooling plate 3 is made of an inorganic polymer compound, such as zinc oxide, aluminum oxide, magnesium oxide, calcium oxide, titanium oxide, nickel oxide, cadmium oxide, bismuth oxide, or niobium oxide.

By means of thermoelectric effect and nano-scale and sintering of an inorganic semiconductor material, the invention is practical for use in cooling a LED module, CPU, or any electronic device that generates heat during operation.

Further, a thermal compound 4 can be applied to bond the heat spreader plate 2 to the LED module 1 and to bond the electronic ceramic cooling plate 3 to the heat spreader plate 2.

Although a particular embodiment of the invention has been described in detail for purposes of illustration, various modifications and enhancements may be made without departing from the spirit and scope of the invention. Accordingly, the invention is not to be limited except as by the appended claims.

What the invention claimed is:

1. A heat exchange cooling structure, comprising:
a heat generating device that generates heat during operation;
a heat spreader plate bonded to a bottom surface of said heat generating device for absorbing heat from said substrate; and
an electronic ceramic cooling plate bonded to a bottom surface of said heat spreader plate for dissipating heat from said heat spreader plate, said electronic ceramic cooling plate being made of a nano-scale inorganic semiconductor material through a sintering process and comprising millions of parallel-connected and series-connected N-P interfaces;
wherein internal N and P types semiconductors of said electronic ceramic cooling plate cause change of current flowing direction so that internal molecules of said electronic ceramic cooling plate collide with one another to produce infrared rays and to carry heat away from said heat spreader plate into the outside open air when said electronic ceramic cooling plate absorbs heat from said heat spreader plate.

2. The heat exchange cooling structure as claimed in claim 1, wherein said heat spreader plate is selectively made from a material group of gold, silver, copper and aluminum.

3. The heat exchange cooling structure as claimed in claim 1, wherein the bonding of the nano-scale inorganic semiconductor material of said electronic ceramic cooling plate to the metal material of said heat spreader plate enables said electronic ceramic cooling plate to absorb heat from said heat spreader plate and internal molecules of said electronic ceramic cooling plate to collide with one another in releasing heat energy subject to thermodynamics

4. The heat exchange cooling structure as claimed in claim 1, wherein said electronic ceramic cooling plate is made of an inorganic polymer compound selected from a group of zinc oxide, aluminum oxide, magnesium oxide, calcium oxide, titanium oxide, nickel oxide, cadmium oxide, bismuth oxide and niobium oxide through a sintering process.

5. The heat exchange cooling structure as claimed in claim 1, wherein said heat generating device is a LED module.

6. The heat exchange cooling structure as claimed in claim 1, wherein said heat generating device is a CPU.

7. The heat exchange cooling structure as claimed in claim 1, wherein said heat generating device is an electronic device of an integrated circuit.

8. The heat exchange cooling structure as claimed in claim 1, further comprising a thermal compound applied to the interfaces between said a heat generating device and said heat spreader plate and between said heat spreader plate and said electronic ceramic cooling plate.
